(19) United States
(12) Patent Application Publication
(10) Pub. No.: US 2026/0004010 A1
(43) Pub. Date: Jan. 1, 2026

(54) METHOD AND SYSTEM FOR IDENTIFYING MULTI-LEVEL THROUGH POCKET FEATURES FROM BOUNDARY REPRESENTATION (B-REP) MODELS

(71) Applicant: HCL Technologies Limited, New Delhi (IN)

(72) Inventors: Akash Agrawal, Pune (IN); Hari Krishnan Elumalai, Chennai (IN); Rajesh Chakravarty, Navi Mumbai (IN)

(21) Appl. No.: 19/078,334

(22) Filed: Mar. 13, 2025

(30) Foreign Application Priority Data
Jun. 27, 2024 (IN) 202411049254

(51) Int. Cl. G06F 30/12

(52) U.S. Cl. CPC G06F 30/12

(57) ABSTRACT

This disclosure relates to method and system for identifying through pocket features having a non-unique entrance face from B-Rep models. The method includes receiving a user input including a B-Rep model. The method further includes identifying a reference shell face from the plurality of faces and an associated reference shell edge based on reference identification criteria. The reference shell face includes the reference shell edge. The method further includes sequentially identifying a set of consecutively adjacent shell faces from remaining of the plurality of faces and a corresponding set of shell edges based on subsequent identification criteria. The method further includes validating a loop formed by the reference shell face and the set of consecutively adjacent shell faces based on through pocket validation criteria.

### TECHNICAL FIELD

This disclosure relates generally to Boundary Representation (B-Rep) models, and more particularly to method and system for identifying multi-level through pocket features from B-Rep models.

### BACKGROUND

Solid modeling is a term that refers to a set of techniques that can be used to create and store computer-based representations of physical objects. Several techniques have evolved over the years for providing computer-based representations of three-dimensional parts. One of the solid modeling techniques is commonly referred to as Boundary Representation (B-Rep). A B-Rep model of a mechanical part includes faces, edges, and vertices which are connected to form a topological structure of the mechanical part. By using B-Rep, many properties (e.g., mass, volume, moments of inertia, products of inertia, etc.) of the mechanical part can be evaluated from an associated B-Rep model. The B-Rep models also enable computer-based analysis of stress and strain in the mechanical part under different loading conditions. B-Rep-based computer models can also be cut and examined in a manner like an actual part.

In the present state of art, numerous feature-based approaches have been developed to recognize machinable features from B-Rep models of mechanical parts. The focus has been on having higher recognition coverage of features like holes, slots, pockets, protrusion, etc., thereby limiting the recognition to happen on simpler configurations. Among holes and pockets, feature recognition research till date is limited to recognition of specific classes of holes and pocket features in B-Rep models due to absence of clear mathematical formalism. However, there exists a class of through pocket features (that exit to, or originate from, more than one face) in a B-rep model that remains largely unconsidered in feature recognition research.

Techniques in the present state of art that attempt to address recognition of relatively complex pocket features make use of face-edge graph generation from the B-Rep model. However, an axis of the pocket features is assumed to be known and based on the axis, the faces of the pocket feature are classified as parallel, anti-parallel, vertical faces, etc. The face-edge graph is simplified using the classified faces and from cycles in the face-edge graph, the pocket feature faces are collected.

There are various limitations to such techniques. The axis of the pocket feature should be known beforehand. It may not be possible to classify the pocket feature faces into parallel, anti-parallel, and/or vertical faces in case of drafted scenario. Further, combinatorial complexity is involved in face-edge graph processing. Such techniques also fail to identify holes bounded by more than one cycle in the face-edge graph.

Thus, the techniques in the present state of art fail to address the problem of efficiently identifying multi-level through pocket features from B-Rep models.

### SUMMARY

In one embodiment, a method for identifying through pocket features having a non-unique entrance face from Boundary Representation (B-Rep) models is disclosed. In one example, the method may include receiving a user input including a B-Rep model. The B-Rep model includes a through pocket. The through pocket includes a plurality of faces. The method may further include identifying a reference shell face from the plurality of faces and an associated reference shell edge based on reference identification criteria. The reference shell face includes the reference shell edge. The method may further include sequentially identifying a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. The first shell edge is opposite to the reference shell edge. A last shell face of the set of consecutively adjacent shell faces is adjacent to the reference shell face. The method may further include validating a loop formed by the reference shell face and the set of consecutively adjacent shell faces based on through pocket validation criteria.

In another embodiment, a system for identifying through pocket features having a non-unique entrance face from B-Rep models is disclosed. In one example, the system may include a processor and a computer-readable medium communicatively coupled to the processor. The computer-readable medium may store processor-executable instructions, which, on execution, may cause the processor to receive a user input including a B-Rep model. The B-Rep model includes a through pocket. The through pocket includes a plurality of faces. The processor-executable instructions, on execution, may further cause the processor to identify a reference shell face from the plurality of faces and an associated reference shell edge based on reference identification criteria. The reference shell face includes the reference shell edge. The processor-executable instructions, on execution, may further cause the processor to sequentially identify a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. The first shell edge is opposite to the reference shell edge. A last shell face of the set of consecutively adjacent shell faces is adjacent to the reference shell face. The processor-executable instructions, on execution, may further cause the processor to validate a loop formed by the reference shell face and the set of consecutively adjacent shell faces based on through pocket validation criteria.

In another embodiment, a non-transitory computer-readable medium storing computer-executable instructions for identifying through pocket features having a non-unique entrance face from B-Rep model is disclosed. In one example, the stored instructions, when executed by a processor, may cause the processor to perform operations including receiving a user input including a B-Rep model. The B-Rep model includes a through pocket. The through pocket includes a plurality of faces. The operations may further include identifying a reference shell face from the plurality of faces and an associated reference shell edge based on reference identification criteria. The reference shell face includes the reference shell edge. The operations may further include sequentially identifying a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. The first shell edge is opposite to the reference shell edge. A last shell face of the set of consecutively adjacent shell faces is adjacent to the reference shell face. The operations may further include validating a loop formed by the reference shell face and the set of consecutively adjacent shell faces based on through pocket validation criteria.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate exemplary embodiments and, together with the description, serve to explain the disclosed principles.

FIG. 1 is a block diagram of an exemplary system for identifying through pocket features having a non-unique entrance face from Boundary Representation (B-Rep) models, in accordance with some embodiments of the present disclosure.

FIG. 2 illustrates a functional block diagram of an exemplary server for-identifying through pocket features having a non-unique entrance face from B-Rep models, in accordance with some embodiments of the present disclosure.

FIG. 3 illustrates a flow diagram of an exemplary process for identifying through pocket features having a non-unique entrance face from B-Rep models, in accordance with some embodiments of the present disclosure.

FIG. 4 illustrates identification of a reference shell face of an exemplary B-Rep model, in accordance with some embodiments of the present disclosure.

FIG. 5 illustrates sequential identification of adjacent shell faces of an exemplary B-Rep model, in accordance with some embodiments of the present disclosure.

FIG. 6 illustrates computation of depth from shell edges of an exemplary B-Rep model, in accordance with some embodiments of the present disclosure.

FIGS. 7A and 7B illustrate valid and invalid through pocket features of an exemplary B-Rep model, in accordance with some embodiments of the present disclosure.

FIG. 8 is a block diagram of an exemplary computer system for implementing embodiments consistent with the present disclosure.

### DETAILED DESCRIPTION

Exemplary embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

The term “concave edge” as referred to herein is defined as an edge of a B-Rep model, where an air angle between faces adjacent to the edge is less than or equal to 180 degrees. It should be noted that the term “concave edge” includes concave and concave-smooth edges.

The term “convex edge” as referred to herein is defined as an edge of a B-Rep model, where an air angle between faces adjacent to the edge is greater than 180 degrees. It should be noted that the term “convex edge” includes convex and convex-smooth edges.

The term “shell face” as referred to herein is defined as an inner face of a pocket feature of a B-Rep model of a solid. The term “shell face” refers to a newly created face upon formation of a pocket after machining of the solid.

The term “shell edge” as referred to herein is defined as a common edge between two adjacent shell faces.

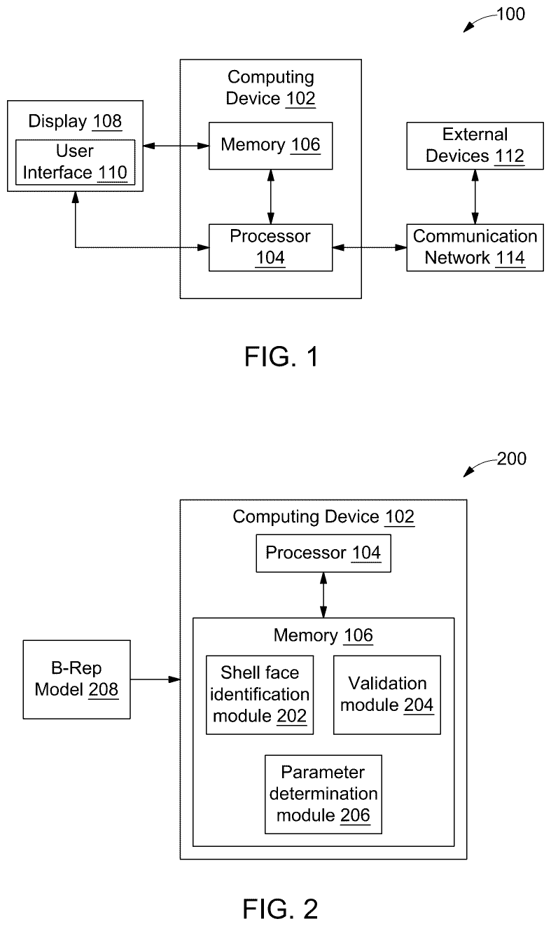

Referring now to FIG. 1, an exemplary system 100 for identifying through pocket features having a non-unique entrance face from Boundary Representation (B-Rep) models is illustrated, in accordance with some embodiments of the present disclosure. The system 100 may include a computing device 102 (for example, server, desktop, laptop, notebook, netbook, tablet, smartphone, mobile phone, or any other computing device), in accordance with some embodiments of the present disclosure. The computing device 102 may identify through pocket features having a non-unique entrance face from B-Rep models. The computing device 102 uses unrecognized faces of a B-Rep model to recognize through pockets (if one exists). The computing device 102 implements a hint-based approach which begins with a reference shell face (i.e., a clue face) and propagates faces of the B-Rep model intelligently to collect feature faces of the through pockets.

As will be described in greater detail in conjunction with FIGS. 2-4, the computing device 102 may receive a user input including a B-Rep model. The B-Rep model includes a through pocket. The through pocket includes a plurality of faces. The computing device 102 may further identify a reference shell face from the plurality of faces and an associated reference shell edge based on reference identification criteria. The reference shell face includes the reference shell edge. The computing device 102 may further sequentially identify a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. A last shell face of the set of consecutively adjacent shell faces is adjacent to the reference shell face. The computing device 102 may further validate a loop formed by the reference shell face and the set of consecutively adjacent shell faces based on through pocket validation criteria.

In some embodiments, the computing device 102 may include one or more processors 104 and a memory 106. Further, the memory 106 may store instructions that, when executed by the one or more processors 104, cause the one or more processors 104 to identify through pocket features having a non-unique entrance face from B-Rep models, in accordance with aspects of the present disclosure. The memory 106 may also store various data (for example, B-Rep model, reference identification criteria, sequential identification criteria, through pocket validation criteria, a set of parameters corresponding to loop and the like) that may be captured, processed, and/or required by the system 100. The memory 106 may be a non-volatile memory (e.g., flash memory, Read Only Memory (ROM), Programmable ROM (PROM), Erasable PROM (EPROM), Electrically EPROM (EEPROM) memory, etc.) or a volatile memory (e.g., Dynamic Random Access Memory (DRAM), Static Random-Access memory (SRAM), etc.).

The system 100 may further include a display 108. The system 100 may interact with a user via a user interface 110 accessible via the display 108. The system 100 may also include one or more external devices 112. In some embodiments, the computing device 102 may interact with the one or more external devices 112 over a communication network 114 for sending or receiving various data. The external devices 112 may include, but may not be limited to, a remote server, a digital device, or another computing system.

Referring now to FIG. 2, a functional block diagram of the computing device 102 for identifying through pocket features having a non-unique entrance face from B-Rep models, in accordance with some embodiments of the present disclosure. FIG. 2 is explained in conjunction with FIG. 1. The computing device 102 may include, within the memory 106, a shell face identification module 202, a validation module 204, and a parameter module 206.

The shell face identification module 202 receives a user input including a B-Rep model 208. The B-Rep model 208 may include a through pocket. The through pocket may include a plurality of faces. Further, the shell face identification module 202 identifies a reference shell face from the plurality of faces and an associated reference shell edge based on reference identification criteria. The reference shell face may include a plurality of edges. The reference shell edge is one of the plurality of edges.

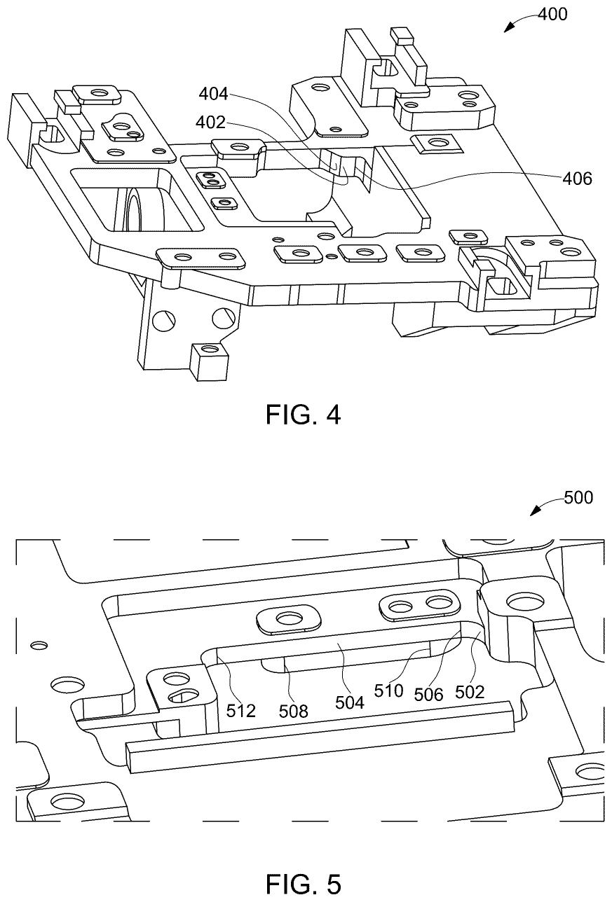

The shell face identification module 202 may implement the reference identification criteria. For each face of the plurality of faces, the reference identification criteria may include identifying at least one concave linear edge from a plurality of edges of the face. Further, the reference identification criteria may include validating each concave linear edge of the at least one concave linear edge based on reference shell edge validation criteria. The reference shell edge validation criteria may be based on a first connection of the concave linear edge with a previous connected edge and a second connection of the concave linear edge with a next connected edge. Upon successful validation, the reference identification criteria may include establishing the concave linear edge as reference shell edge and the face as the reference shell face. This is explained in greater detail in conjunction with FIG. 4.

Further, the shell face identification module 202 sequentially identifies a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. The first shell face is opposite to the reference shell edge. A last shell face of the set of consecutively adjacent shell faces is adjacent to the reference shell face. Thus, the reference shell face and the set of consecutively adjacent shell faces may form a loop.

The shell face identification module 202 may implement the subsequent identification criteria. For each of the remaining of the plurality of faces, the subsequent identification criteria may include determining whether the face includes at least one opposite linear edge to an associated shell edge for each face of the remaining of the plurality of faces. Further the subsequent identification criteria may include validating each opposite linear edge of the at least one opposite linear edge based on subsequent shell edge validation criteria. The subsequent shell edge validation criteria may be based on at least one of concavity or convexity of the opposite linear edge with a previous edge and a next edge and distance of the opposite linear edge from a previous shell edge. Upon successful validation, the subsequent identification criteria may include establishing the opposite linear edge as a shell edge and the face as the consecutively adjacent shell face. This is explained in greater detail in conjunction with FIG. 5.

The parameter determination module 206 determines a set of parameters corresponding to the loop formed by the reference shell face and the set of consecutively adjacent shell faces. By way of an example, the set of parameters may include an axis of the loop, depth of the loop, perimeter of the loop, area enclosed by the loop, and the like. To Determine the set of parameters, the parameter determination module 206 may determine the axis of the loop based on a direction of each shell edge of the reference shell edge and the set of shell edges. Further, the parameter determination module 206 may calculate the depth of the loop based on a projected image length of the reference shell edge and the set of shell edges on the axis. Further, the parameter determination module 206 may calculate the area enclosed by the loop. In some embodiments, the parameter determination module 206 may also calculate the perimeter of the loop.

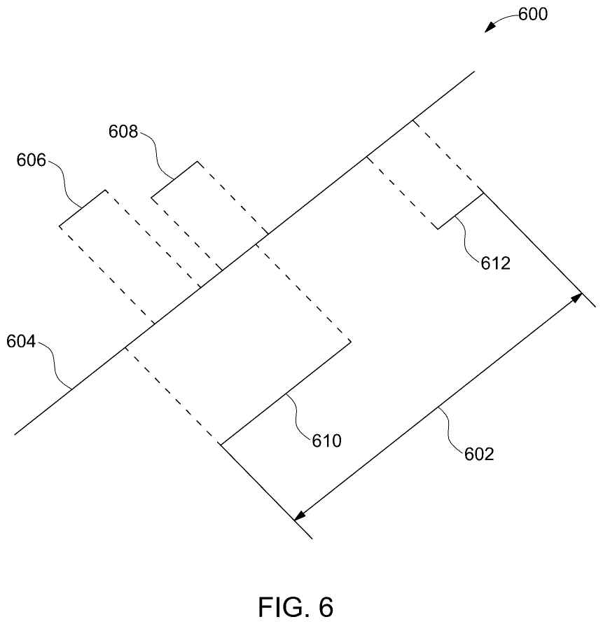

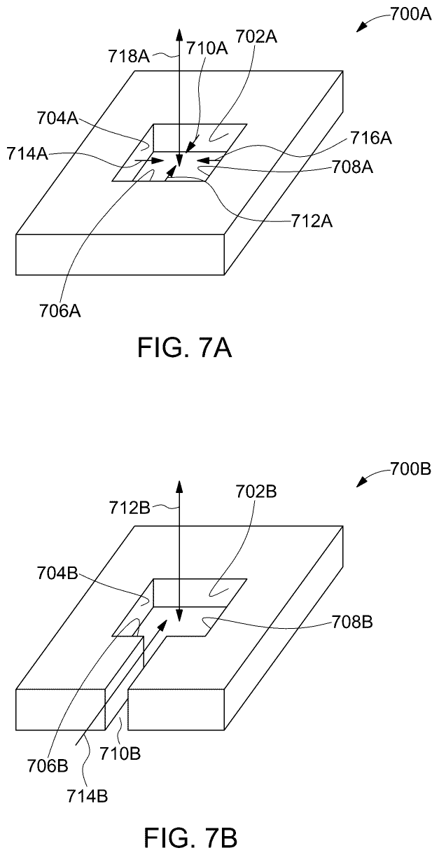

The validation module 204 may validate the loop formed by the reference shell face and the set of consecutively adjacent shell faces based on through pocket validation criteria. The validation module 204 may implement the through pocket validation criteria. For each shell face of the loop, the through pocket validation criteria may include determining an absence of a concave edge in a plurality of non-shell edges of the shell face within an extent of the depth. Further, the through pocket validation criteria may include determining an absence of an opening to access the loop in a direction other than a direction of the axis. The through pocket validation criteria may include checking for an opening to access the feature in a direction. Each shell face of the pocket feature should be blocked by other shell face of the same pocket feature. Further, the through pocket validation criteria may include establishing the loop as a valid through pocket feature when the concave edge is absent in the plurality of non-shell edges and the opening is absent in a direction other than the direction of the axis. The determination of the valid through pocket feature, by the validation module 204, is based on the observation that any through pocket feature in a B-Rep model is bounded by at least one simple cycle of faces forming a closed polygon when projected onto a plane that is perpendicular to feature axis. This is explained in greater detail in conjunction with FIGS. 6 and 7A-B.

After the validation module 204 establishes the loop as a valid through pocket feature, the parameter determination module 206 may define the perimeter of the swept area capable of forming the through pocket feature. Alternatively, the parameter determination module 206 may calculate the area enclosed by the through pocket feature.

It should be noted that all such aforementioned modules 202-206 may be represented as a single module or a combination of different modules. Further, as will be appreciated by those skilled in the art, each of the modules 202-206 may reside, in whole or in parts, on one device or multiple devices in communication with each other. In some embodiments, each of the modules 202-206 may be implemented as dedicated hardware circuit including custom application-specific integrated circuit (ASIC) or gate arrays, off-the-shelf semiconductors such as logic chips, transistors, or other discrete components. Each of the modules 202-206 may also be implemented in a programmable hardware device such as a field programmable gate array (FPGA), programmable array logic, programmable logic device, and so forth. Alternatively, each of the modules 202-206 may be implemented in software for execution by various types of processors (e.g., processor 104). An identified module of executable code may, for instance, include one or more physical or logical blocks of computer instructions, which may, for instance, be organized as an object, procedure, function, or other construct. Nevertheless, the executables of an identified module or component need not be physically located together but may include disparate instructions stored in different locations which, when joined logically together, include the module and achieve the stated purpose of the module. Indeed, a module of executable code could be a single instruction, or many instructions, and may even be distributed over several different code segments, among different applications, and across several memory devices.

As will be appreciated by one skilled in the art, a variety of processes may be employed for identifying through pocket features having a non-unique entrance face from B-Rep models. For example, the exemplary system 100 and the associated computing device 102, 200 may identify through pocket features having a non-unique entrance face from B-Rep models by the processes discussed herein. In particular, as will be appreciated by those of ordinary skill in the art, control logic and/or automated routines for performing the techniques and steps described herein may be implemented by the system 100 and the associated computing device 102, 200 either by hardware, software, or combinations of hardware and software. For example, suitable code may be accessed and executed by the one or more processors on the system 100 to perform some or all of the techniques described herein. Similarly, application specific integrated circuits (ASICs) configured to perform some, or all of the processes described herein may be included in the one or more processors on the system 100.

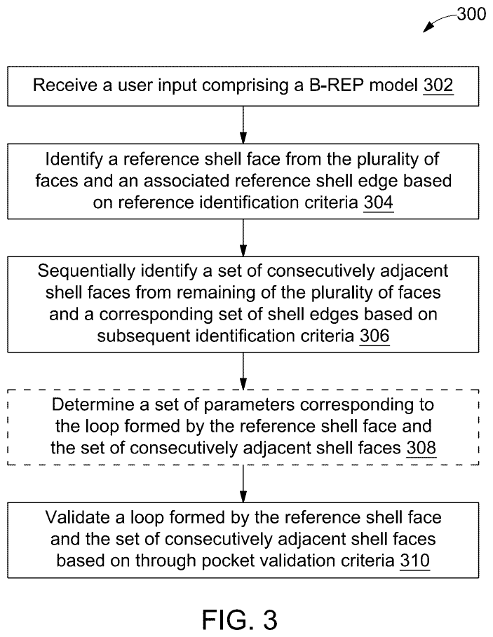

Referring now to FIG. 3, an exemplary process 300 for identifying through pocket features having a non-unique entrance face from B-Rep models is depicted via a flowchart, in accordance with some embodiments of the present disclosure. FIG. 3 is explained in conjunction with FIGS. 1 and 2. The process 300 may be implemented by the computing device 102 of the system 100. The process 300 may include receiving, by the shell face identification module 202, a user input including a B-Rep model 208 (for example, the B-Rep model 208), at step 302. It may be noted that the B-Rep model 208 includes a through pocket. The through pocket may include a plurality of faces.

Further, the process 300 may include identifying, by the shell face identification module 202, a reference shell face from the plurality of faces and an associated reference shell edge based on reference identification criteria, at step 304. The reference face includes the reference shell edge. For each of the plurality of faces, the reference identification criteria may include identifying, by shell face identification module 202, at least one concave linear edge from a plurality of edges of the face. Further, the reference identification criteria may include validating, by shell face identification module 202, each concave linear edge of the at least one concave linear edge, based on reference shell edge validation criteria. The reference shell edge validation criteria may be based on a first connection of the concave linear edge with a previous connected edge and a second connection of the concave linear edge with a next connected edge. Upon successful validation, the reference identification criteria may include establishing, by shell face identification module 202, the concave linear edge as the reference shell edge and the face as the reference shell face.

The process 300 may include sequentially identifying, by shell face identification module 202, a set of consecutively adjacent shell faces from remaining of the plurality of faces and a corresponding set of shell edges based on subsequent identification criteria, at step 306. A first shell face of the set of consecutively adjacent shell faces is adjacent to the reference shell face. The first shell face includes the reference shell edge and a first shell edge. The first shell edge is opposite to the reference shell edge. A last shell face of the set of consecutively adjacent shell faces is adjacent to the reference shell face. For each of the remaining of the plurality of faces, the subsequent identification criteria may include determining, by shell face identification module 202, whether the face includes at least one opposite linear edge to an associated shell edge. Further, the subsequent identification criteria may include validating, by shell face identification module 202, each opposite linear edge of the at least one opposite linear edge based on subsequent shell edge validation criteria. The subsequent shell edge validation criteria may be based on at least one of concavity or convexity of the opposite linear edge, accessibility of the opposite linear edge, connection of the opposite linear edge with a previous edge and a next edge, and distance of the opposite linear edge from a previous shell edge. Upon successful validation, the subsequent shell edge validation criteria may include establishing, by shell face identification module 202, the opposite linear edge as a shell edge and the face as a consecutively adjacent shell face.

The process 300 may include determining, by the parameter determination module 206, a set of parameters corresponding to the loop formed by the reference shell face and the set of consecutively adjacent shell faces, at step 308. By way of an example, the set of parameters may include, but may not be limited to, an axis of the loop, depth of the loop, perimeter of the loop, area enclosed by the loop, and the like. Further, the step 308 of the process 300 may include determining, by the parameter determination module 206, the axis of the loop based on a direction of each shell edge of the reference shell edge and the set of shell edges. Further, the step 308 of the process 300 may include calculating, by the parameter determination module 206, the depth of the loop based on a projected image length of the reference shell edge and the set of shell edges on the axis. Further, the step 308 of the process 300 may include calculating, by the parameter determination module 206, the area enclosed by the loop.

The process 300 may include validating, by the validation module 204, a loop formed by the reference shell face and the set of consecutively adjacent shell faces based on through pocket validation criteria, at step 310. For each shell face of the loop, the through pocket validation criteria may include determining, by the validation module 204, an absence of a concave edge in a plurality of non-shell edges of the shell face within an extent of the depth. Further, the through pocket validation criteria may include establishing, by the validation module 204, the loop as a valid through pocket feature when the concave edge is absent in the plurality of non-shell edges and the opening is absent in a direction other than the direction of the axis.

Referring now to FIG. 4, identification of a reference shell face of an exemplary B-Rep model 400 is illustrated, in accordance with some embodiments of the present disclosure. FIG. 4 is explained in conjunction with FIGS. 1, 2, and 3. The B-Rep model 400 may be analogous to the B-Rep model 208. The shell face identification module 202 may receive the B-Rep model 400 as a user input. The B-Rep model 400 includes a through pocket. The through pocket includes a plurality of faces (such as a face 402 and a face 404). The shell face identification module 202 may then identify a reference shell face (i.e., a clue face) from the plurality of faces of the through pocket based on reference identification criteria.

In some embodiments, while evaluating whether a face (for example, the face 402) is a reference shell face, a first condition of the reference identification criteria may be that the face 402 should be an extrude face with one concavely connected linear edge 406. Further, the reference identification criteria may include 3 additional conditions. If the face 402 meets one of the 3 conditions, the face is identified as the reference shell face. The first additional condition is that vertices of the concavely connected linear edge 406 should be convex vertices and a next edge and a previous edge of the concavely connected linear edge 406 should be convex edges. The second additional condition is applied when either one of the next edge or the previous edge is a concave edge. According to the second additional condition, a junction vertex between the concave adjacent edge and the concavely connected linear edge 406 should be a concave vertex, and a junction vertex between the convex adjacent edge and the concavely connected edge should be a convex vertex. The third additional condition is applied when both the next edge and the previous edge are concave edges. According to the third additional condition, both the vertices of the concavely connected linear edge 406 should be concave vertices. Once the first condition and one of the 3 additional conditions of the reference face identification criteria are satisfied, the concavely connected linear edge 406 is tagged as a shell edge and the face 402 associated with the concavely connected linear edge 406 is tagged as a reference shell face.

Further, upon identification of the reference shell face and the associated reference shell edge, the shell face identification module 202 evaluates the face 404 (which is adjacent to the face 402 and is also associated with the concavely connected linear edge 406) based on subsequent identification criteria. In other words, the concavely connected linear edge 406 is associated with the face 402 on one side and the face 404 on the other side. Upon identifying the face 404 as a shell face and a shell edge associated with the face 404 (other than the reference shell edge), the shell face identification module 202 may evaluate a face adjacent to the face 404 (i.e., a face that shares the shell edge on the other side) based on the subsequent identification criteria. This evaluation of consequently adjacent faces of the through pocket continues until the shell identification module 202 reaches the reference shell face. In other words, the evaluation continues until each face of the through pocket has been evaluated by the shell identification module 202. This is explained in greater detail in conjunction with FIG. 5.

Referring now to FIG. 5, sequential identification of adjacent shell faces of an exemplary B-Rep model 500 is illustrated, in accordance with some embodiments of the present disclosure. FIG. 5 is explained in conjunction with FIGS. 1, 2, 3, and 4. The B-Rep model 500 may be analogous to the B-Rep model 208. Upon identifying the reference shell face and the associated reference shell edge, the shell face identification module 202 sequentially identifies a set of consecutively adjacent shell faces from remaining of the plurality of faces and a corresponding set of shell edges based on the subsequent identification criteria.

The B-Rep model 500 may include a through pocket feature. The through pocket feature may include a plurality of faces (such as a face 502 and a face 504). In an embodiment, the shell face identification module 202 determines the face 502 as a shell face and an associated shell edge 506 based on one of the reference identification criteria or the subsequent identification criteria (depending on whether the reference shell face is already identified or not).

Further, the shell face identification module 202 evaluates the face 504 (which is adjacent to the shell face 502 and associated with the shell edge 506) based on the subsequent identification criteria. To implement the subsequent identification criteria, the shell face identification module 202 may determine whether the face includes at least one opposite linear edge to the shell edge 506. It should be noted that two edges of a face are opposite to each other if their associated co-edge directions are opposite and each edge in the pair lies in an interior direction of the other edge. Thus, for the B-Rep model 500, the at least one opposite linear edge may include an edge 508, an edge 510, and an edge 512.

If an opposite linear edge is not found, then the shell face identification module 202 may terminate the propagation through the adjacent faces, and the face 504 is not added as a shell face, in accordance with the subsequent identification criteria.

If the shell face identification module 202 identifies the at least one opposite linear edge, the shell face identification module 202 may validate each opposite linear edge of the at least one opposite linear edge based on subsequent shell edge validation criteria. The subsequent shell edge validation criteria may be based on at least one of concavity or convexity of the opposite linear edge, accessibility of the opposite linear edge, connection of the opposite linear edge with a previous edge and a next edge, and distance of the opposite linear edge from a previous shell edge.

In an embodiment, if the count of the at least one opposite linear edge is one (i.e., a single opposite linear edge is identified) and that opposite linear edge is a concave edge (e.g., the edge 512), then the opposite linear edge should be accessible based on the reference face identification criteria (i.e., the opposite linear edge should meet one of the 3 additional conditions). If the count of the other opposite linear edge is one (i.e., a single opposite linear edge is identified) and that opposite linear edge is a convex edge (e.g., the edge 508 or the edge 510), then for accessibility, both vertices of the linear edge should be convex vertices. Additionally, the next edge and previous edge from the opposite linear edge should also be convex edges. If any of the above mentioned two conditions when the count of the at least one opposite linear edge is one is not satisfied, then the shell face identification module 202 may identify the opposite linear edge as a next shell edge. If any of the above mentioned two conditions when the count of the at least one opposite linear edge is one is not satisfied, then the shell face identification module 202 may terminate the propagation, and the face 504 is not added as a shell face, in accordance with the subsequent identification criteria.

If the count of the at least one opposite linear edge is more than one (i.e., multiple opposite linear edges are identified), the choice of the next shell edge among the list of opposite linear edges is based on identifying concave edges (i.e., the edge 512) and convex edges (i.e., the edge 508 and the edge 510) from the at least one opposite linear edge. If concave edges are present, then a concave edge which is closest to the already identified shell edge 506 is identified as the next shell edge provided that the concave edge satisfies the reference face identification criteria (i.e., the concave edge should meet one of the 3 additional conditions). If convex edges are present, then a convex edge which is farthest to the already identified shell edge 506 is identified as the next shell edge provided that both vertices of the convex edge are convex vertices, and the next edge and the previous edge from the convex edge are also convex edges. If any of the above mentioned two conditions when the count of the at least one opposite linear edge is more than one is not satisfied, then the shell face identification module 202 may terminate the propagation, and the face 504 is not added as a shell face, in accordance with the subsequent identification criteria.

Thus, the edge 512 is identified as a shell edge based on the subsequent identification criteria. Once a linear opposite edge is identified as a shell edge, the shell face identification module 202 identifies the associated face as a shell face. Thus, the face 504 is identified as a shell face. As each of the faces of the through pocket gets tagged as a shell face, the adjacent face of the next shell edge is again tested based on the subsequent identification criteria and the propagation (i.e., evaluation) continues till it reaches the reference shell face from which it started.

Referring now to FIG. 6, computation of depth 602 from shell edges of an exemplary B-Rep model (for example, the B-Rep model 208) is illustrated, in accordance with some embodiments of the present disclosure. FIG. 6 is explained in conjunction with FIGS. 1, 2, 3, 4, and 5. Once the shell face identification module 202 identifies all shell faces (including the reference shell face and the set of consecutively adjacent shell faces) and shell edges (including the reference shell edge and the set of shell edges), the parameter determination module 206 determines a set of parameters corresponding to the loop formed by the shell faces of the through pocket. The set of parameters includes, but is not limited to, an axis 604 of the loop, the depth 602 of the loop, perimeter of the loop, and area enclosed by the loop.

The parameter determination module 206 determines the axis 604 of the loop based on a direction of each of the shell edges. Further, the parameter determination module 206 calculates the depth 602 of the loop as a total projected image length of all the shell edges on the axis 604. For example, the loop may include 4 shell edges, i.e., a first shell edge, a second shell edge, a third shell edge, and a fourth shell edge. The parameter determination module 206 may project a length 606 of the first shell edge, a length 608 of the second shell edge, a length 610 of the third shell edge, and a length 612 of the fourth shell edge on the axis 604. The parameter determination module 206 then determines the depth 602 as the total projected image length of the 4 shell edges on the axis 604.

Referring now to FIGS. 7A and 7B, valid and invalid through pocket features of an exemplary B-Rep model (for example, the B-Rep model 208) are illustrated, in accordance with some embodiments of the present disclosure. FIGS. 7A and 7B are explained in conjunction with FIGS. 1, 2, 3, 4, 5, and 6. Once the parameter determination module 206 calculates the depth, the validation module 204 may evaluate each of the identified shell faces of the loop for a presence of a concave edge other than the identified shell edges within extents of the depth. Presence of a non-shell edge concave edge may indicate presence of an obstruction. Thus, the validation module 204 may establish that the loop is an invalid through pocket feature.

Further, the validation module 204 may check for an opening to access the loop in a direction other than the direction of the axis of the through pocket. Further, the validation module 204, each shell face of the loop should be blocked by another shell face of the same loop.

The validation step of checking for access to the loop from a direction other than a direction of the axis is computationally expensive as it involves checking if any portion of the shell face is visible in a direction other than that of the axis. To overcome this limitation, the validation module 204 uses normals of the plurality of shell faces. A shell face blocks another shell face if normals of both the shell faces are in opposite directions and one shell face lies ahead of the other shell face by following the direction of the normal of the other shell face and vice-versa.

In FIG. 7A, a loop 700A is shown. The loop 700A includes a plurality of shell faces (i.e., a shell face 702A, a shell face 704A, a shell face 706A, and a shell face 708A). Each of the plurality of shell faces is blocked by another of the plurality of shell faces. Further, a normal of each of the plurality of shell faces is in opposite direction to a normal of another of the plurality of shell faces. For example, a normal 710A of the shell face 702A and a normal 712A of the shell face 706A are in opposite directions to each other. Also, a normal 714A of the shell face 704A and a normal 716A of the shell face 708A are in opposite directions to each other. The loop 700A is accessible along a direction 718A of the shell edges. Also, the loop 700B is not accessible from any other direction. Thus, the validation module 204 establishes the loop 700A as a valid through pocket feature.

In FIG. 7B, a loop 700B is shown. The loop 700B includes a plurality of shell faces (i.e., a shell face 702B, a shell face 704B, a shell face 706B, and a shell face 708B). Each of the plurality of shell faces is not completely blocked by another of the plurality of shell faces. The shell face 706B does not completely block the shell face 702B due to presence of an opening 710B. Thus, the loop 700B is accessible along a direction 712B of the shell edges and along another direction 714B along the opening. Thus, the validation module 204 establishes the loop 700B as an invalid through pocket feature.

After the validation module 204 establishes the loop as a valid through pocket feature, the parameter determination module 206 determines the area of the swept area capable of forming the through pocket feature.

As will be also appreciated, the above-described techniques may take the form of computer or controller implemented processes and apparatuses for practicing those processes. The disclosure can also be embodied in the form of computer program code containing instructions embodied in tangible media, such as floppy diskettes, solid state drives, CD-ROMs, hard drives, or any other computer-readable storage medium, wherein, when the computer program code is loaded into and executed by a computer or controller, the computer becomes an apparatus for practicing the invention. The disclosure may also be embodied in the form of computer program code or signal, for example, whether stored in a storage medium, loaded into and/or executed by a computer or controller, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented on a general-purpose microprocessor, the computer program code segments configure the microprocessor to create specific logic circuits.

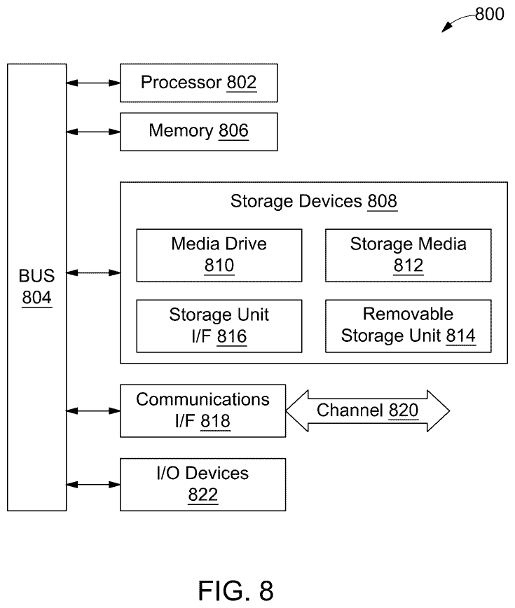

The disclosed methods and systems may be implemented on a conventional or a general-purpose computer system, such as a personal computer (PC) or server computer. Referring now to FIG. 8, an exemplary computing system 800 that may be employed to implement processing functionality for various embodiments (e.g., as a SIMD device, client device, server device, one or more processors, or the like) is illustrated. Those skilled in the relevant art will also recognize how to implement the invention using other computer systems or architectures. The computing system 800 may represent, for example, a user device such as a desktop, a laptop, a mobile phone, personal entertainment device, DVR, and so on, or any other type of special or general-purpose computing device as may be desirable or appropriate for a given application or environment. The computing system 800 may include one or more processors, such as a processor 802 that may be implemented using a general or special purpose processing engine such as, for example, a microprocessor, microcontroller or other control logic. In this example, the processor 802 is connected to a bus 804 or other communication medium. In some embodiments, the processor 802 may be an Artificial Intelligence (AI) processor, which may be implemented as a Tensor Processing Unit (TPU), or a graphical processor unit, or a custom programmable solution Field-Programmable Gate Array (FPGA).

The computing system 800 may also include a memory 806 (main memory), for example, Random Access Memory (RAM) or other dynamic memory, for storing information and instructions to be executed by the processor 802. The memory 806 also may be used for storing temporary variables or other intermediate information during execution of instructions to be executed by the processor 802. The computing system 800 may likewise include a read only memory (“ROM”) or other static storage device coupled to bus 804 for storing static information and instructions for the processor 802.

The computing system 800 may also include a storage device 808, which may include, for example, a media drive 810 and a removable storage interface. The media drive 810 may include a drive or other mechanism to support fixed or removable storage media, such as a hard disk drive, a floppy disk drive, a magnetic tape drive, an SD card port, a USB port, a micro-USB, an optical disk drive, a CD or DVD drive (R or RW), or other removable or fixed media drive. A storage media 812 may include, for example, a hard disk, magnetic tape, flash drive, or other fixed or removable medium that is read by and written to by the media drive 810. As these examples illustrate, the storage media 812 may include a computer-readable storage medium having stored there in particular computer software or data.

In alternative embodiments, the storage devices 808 may include other similar instrumentalities for allowing computer programs or other instructions or data to be loaded into the computing system 800. Such instrumentalities may include, for example, a removable storage unit 814 and a storage unit interface 816, such as a program cartridge and cartridge interface, a removable memory (for example, a flash memory or other removable memory module) and memory slot, and other removable storage units and interfaces that allow software and data to be transferred from the removable storage unit 814 to the computing system 800.

The computing system 800 may also include a communications interface 818. The communications interface 818 may be used to allow software and data to be transferred between the computing system 800 and external devices. Examples of the communications interface 818 may include a network interface (such as an Ethernet or other NIC card), a communications port (such as for example, a USB port, a micro-USB port), Near field Communication (NFC), etc. Software and data transferred via the communications interface 818 are in the form of signals which may be electronic, electromagnetic, optical, or other signals capable of being received by the communications interface 818. These signals are provided to the communications interface 818 via a channel 820. The channel 820 may carry signals and may be implemented using a wireless medium, wire or cable, fiber optics, or another communications medium. Some examples of the channel 820 may include a phone line, a cellular phone link, an RF link, a Bluetooth link, a network interface, a local or wide area network, and other communications channels.

The computing system 800 may further include Input/Output (I/O) devices 822. Examples may include, but are not limited to a display, keypad, microphone, audio speakers, vibrating motor, LED lights, etc. The I/O devices 822 may receive input from a user and also display an output of the computation performed by the processor 802. In this document, the terms “computer program product” and “computer-readable medium” may be used generally to refer to media such as, for example, the memory 806, the storage devices 808, the removable storage unit 814, or signal(s) on the channel 820. These and other forms of computer-readable media may be involved in providing one or more sequences of one or more instructions to the processor 802 for execution. Such instructions, generally referred to as “computer program code” (which may be grouped in the form of computer programs or other groupings), when executed, enable the computing system 800 to perform features or functions of embodiments of the present invention.

In an embodiment where the elements are implemented using software, the software may be stored in a computer-readable medium and loaded into the computing system 800 using, for example, the removable storage unit 814, the media drive 810 or the communications interface 818. The control logic (in this example, software instructions or computer program code), when executed by the processor 802, causes the processor 802 to perform the functions of the invention as described herein.

Thus, the disclosed method and system try to overcome the technical problem of identifying through pocket features having a non-unique entrance face from Boundary Representation (B-Rep) models. The disclosed method and system may receive a user input including a B-Rep model. The B-Rep model includes a through pocket. The through pocket includes a plurality of faces. Further, the disclosed method and system may identify a reference shell face from the plurality of faces and an associated reference shell edge based on reference identification criteria. The reference shell face includes the reference shell edge. Moreover, the disclosed method and system may sequentially identify a set of consecutively adjacent shell faces from remaining of the plurality of faces and a corresponding set of shell edges based on subsequent identification criteria. A first shell face of the set of consecutively adjacent shell faces is adjacent to the reference shell face. The first shell face includes the reference shell edge and a first shell edge. The first shell edge is opposite to the reference shell edge. A last shell face of the set of consecutively adjacent shell faces is adjacent to the reference shell face Thereafter, the disclosed method and system may validate a loop formed by the reference shell face and the set of consecutively adjacent shell faces based on through pocket validation criteria.

As will be appreciated by those skilled in the art, the techniques described in the various embodiments discussed above are not routine, or conventional, or well understood in the art. The techniques provide an algorithm which primarily works with traversing the topology of the B-Rep model and as no explicit graph data structure is created and modified for recognition of through pocket features, the algorithm by passes the combinatorial overhead of graph processing. An algorithm for identifying through pockets with non-unique entrance faces from B-Rep models, that uses a B-Rep topology traversal, and the validation criteria has been presented. It is simple and yet powerful and has been demonstrated to be successful in identifying complex through pocket features in real world parts. Additionally, the techniques are applicable in manufacturing domain.

In light of the above-mentioned advantages and the technical advancements provided by the disclosed method and system, the claimed steps as discussed above are not routine, conventional, or well understood in the art, as the claimed steps enable the following solutions to the existing problems in conventional technologies. Further, the claimed steps clearly bring an improvement in the functioning of the device itself as the claimed steps provide a technical solution to a technical problem.

The specification has described method and system for identifying through pocket features having non-unique entrance face from B-Rep models. The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

It is intended that the disclosure and examples be considered as exemplary only, with a true scope and spirit of disclosed embodiments being indicated by the following claims.

What is claimed is:

1. A method for identifying through pocket features having a non-unique entrance face from Boundary Representation (B-Rep) models, the method comprising:
receiving, by a computing device, a user input comprising a B-Rep model, wherein the B-Rep model comprises a through pocket, and wherein the through pocket comprises a plurality of faces;
identifying, by the computing device, a reference shell face from the plurality of faces and an associated reference shell edge based on reference identification criteria, wherein the reference shell face comprises the reference shell edge;
sequentially identifying, by the computing device, a set of consecutively adjacent shell faces from remaining of the plurality of faces and a corresponding set of shell edges based on subsequent identification criteria, wherein:
a first shell face of the set of consecutively adjacent shell faces is adjacent to the reference shell face,
the first shell face comprises the reference shell edge and a first shell edge,
the first shell edge is opposite to the reference shell edge, and
a last shell face of the set of consecutively adjacent shell faces is adjacent to the reference shell face; and
validating, by the computing device, a loop formed by the reference shell face and the set of consecutively adjacent shell faces based on through pocket validation criteria.

2. The method of claim 1, wherein the reference identification criteria comprise:
for each face of the plurality of faces,
identifying at least one concave linear edge from a plurality of edges of the face;
validating each concave linear edge of the at least one concave linear edge, based on reference shell edge validation criteria, wherein the reference shell edge validation criteria is based on a first connection of the concave linear edge with a previous connected edge and a second connection of the concave linear edge with a next connected edge; and
upon successful validation, establishing the concave linear edge as the reference shell edge and the face as the reference shell face.

3. The method of claim 1, wherein the subsequent identification criteria comprise:
for each face of the remaining of the plurality of faces,
determining whether the face comprises at least one opposite linear edge to an associated shell edge;
validating each opposite linear edge of the at least one opposite linear edge based on subsequent shell edge validation criteria, wherein the subsequent shell edge validation criteria is based on at least one of concavity or convexity of the opposite linear edge, accessibility of the opposite linear edge, connection of the opposite linear edge with a previous edge and a next edge, and distance of the opposite linear edge from a previous shell edge; and
upon successful validation, establishing the opposite linear edge as a shell edge and the face as a consecutively adjacent shell face.

4. The method of claim 1, further comprising determining a set of parameters corresponding to the loop formed by the reference shell face and the set of consecutively adjacent shell faces, wherein the set of parameters comprises an axis of the loop, depth of the loop, and area enclosed by the loop.

5. The method of claim 4, wherein determining the set of parameters corresponding to the loop formed by the reference shell face and the set of consecutively adjacent shell faces comprises:
determining the axis of the loop based on a direction of each shell edge of the reference shell edge and the set of shell edges;
calculating the depth of the loop based on a projected image length of the reference shell edge and the set of shell edges on the axis; and
calculating the area enclosed by the loop.

6. The method of claim 4, wherein the through pocket validation criteria comprise:
for each shell face of the loop, determining an absence of a concave edge in a plurality of non-shell edges of the shell face within an extent of the depth;
determining an absence of an opening to access the loop in a direction other than a direction of the axis;
and
establishing the loop as a valid through pocket feature when:
the concave edge is absent in the plurality of non-shell edges, and
the opening is absent in a direction other than the direction of the axis.

7. A system for identifying through pocket features having a non-unique entrance face from Boundary Representation (B-Rep) models, the system comprising:
a processor; and
a memory communicatively coupled to the processor, wherein the memory stores processor instructions, which when executed by the processor, cause the processor to:
receive a user input comprising a B-Rep model, wherein the B-Rep model comprises a through pocket, and wherein the through pocket comprises a plurality of faces;
identify a reference shell face from the plurality of faces and an associated reference shell edge based on reference identification criteria, wherein the reference shell face comprises the reference shell edge;
sequentially identify a set of consecutively adjacent shell faces from remaining of the plurality of faces and a corresponding set of shell edges based on subsequent identification criteria, wherein:
a first shell face of the set of consecutively adjacent shell faces is adjacent to the reference shell face,
the first shell face comprises the reference shell edge and a first shell edge,
the first shell edge is opposite to the reference shell edge, and
a last shell face of the set of consecutively adjacent shell faces is adjacent to the reference shell face; and
validate a loop formed by the reference shell face and the set of consecutively adjacent shell faces based on through pocket validation criteria.

8. The system of claim 7, wherein the reference identification criteria comprise:
for each face of the plurality of faces,
identify at least one concave linear edge from a plurality of edges of the face;
validate each concave linear edge of the at least one concave linear edge, based on reference shell edge validation criteria, wherein the reference shell edge validation criteria are based on a first connection of the concave linear edge with a previous connected edge and a second connection of the concave linear edge with a next connected edge; and
upon successful validation, establish the concave linear edge as the reference shell edge and the face as the reference shell face.

9. The system of claim 7, wherein to subsequently identify the set of adjacent shell face, the processor instructions, on execution, further cause the processor to:
for each face of the remaining of the plurality of faces,
determine whether the face comprises at least one opposite linear edge to an associated shell edge;
validate each opposite linear edge of the at least one opposite linear edge based on subsequent shell edge validation criteria, wherein the subsequent shell edge validation criteria is based on at least one of concavity or convexity of the opposite linear edge, accessibility of the opposite linear edge, connection of the opposite linear edge with a previous edge and a next edge, and distance of the opposite linear edge from a previous shell edge; and
upon successful validation, establish the opposite linear edge as a shell edge and the face as a consecutively adjacent shell face.

10. The system of claim 7, wherein the processor instructions, on execution, further cause the processor to determine a set of parameters corresponding to the loop formed by the reference shell face and the set of consecutively adjacent shell faces, wherein the set of parameters comprises an axis of the loop, depth of the loop, and area enclosed by the loop.

11. The system of claim 10, wherein to determine the set of parameters corresponding to the loop formed by the reference shell face and the set of consecutively adjacent shell face, the processor instructions, on execution, further cause the processor to:
determine the axis of the loop based on a direction of each shell edge of the reference shell edge and the set of shell edges;
calculate the depth of the loop based on a projected image length of the reference shell edge and the set of shell edges on the axis; and
calculate the area enclosed by the loop.

12. The system of claim 10, wherein the through pocket validation criteria comprise:
for each shell face of the loop, determine an absence of a concave edge in a plurality of non-shell edges of the shell face within an extent of the depth;
determine an absence of an opening to access the loop in a direction other than a direction of the axis;
and
establish the loop as a valid through pocket feature when:
the concave edge is absent in the plurality of non-shell edges, and
the opening is absent in a direction other than the direction of the axis.

13. A non-transitory computer-readable medium storing computer-executable instructions for identifying through pocket features having a non-unique entrance face from Boundary Representation (B-Rep) models, the computer-executable instructions configured for:
receiving a user input comprising a B-Rep model, wherein the B-Rep model comprises a through pocket, and wherein the through pocket comprises a plurality of faces;
identifying a reference shell face from the plurality of faces and an associated reference shell edge based on reference identification criteria, wherein the reference shell face comprises the reference shell edge;
sequentially identifying a set of consecutively adjacent shell faces from remaining of the plurality of faces and a corresponding set of shell edges based on subsequent identification criteria, wherein:
a first shell face of the set of consecutively adjacent shell faces is adjacent to the reference shell face,
the first shell face comprises the reference shell edge and a first shell edge,
the first shell edge is opposite to the reference shell edge, and
a last shell face of the set of consecutively adjacent shell faces is adjacent to the reference shell face; and
validating a loop formed by the reference shell face and the set of consecutively adjacent shell faces based on through pocket validation criteria.

14. The non-transitory computer-readable medium of claim 13, wherein the reference identification criteria comprise:
for each face of the plurality of faces,
identifying at least one concave linear edge from a plurality of edges of the face;
validating each concave linear edge of the at least one concave linear edge, based on reference shell edge validation criteria, wherein the reference shell edge validation criteria is based on a first connection of the concave linear edge with a previous connected edge and a second connection of the concave linear edge with a next connected edge; and
upon successful validation, establishing the concave linear edge as the reference shell edge and the face as the reference shell face.

15. The non-transitory computer-readable medium of claim 13, wherein the subsequent identification criteria comprise:
for each face of the remaining of the plurality of faces,
determining whether the face comprises at least one opposite linear edge to an associated shell edge;
validating each opposite linear edge of the at least one opposite linear edge based on subsequent shell edge validation criteria, wherein the subsequent shell edge validation criteria is based on at least one of concavity or convexity of the opposite linear edge, accessibility of the opposite linear edge, connection of the opposite linear edge with a previous edge and a next edge, and distance of the opposite linear edge from a previous shell edge; and
upon successful validation, establishing the opposite linear edge as a shell edge and the face as a consecutively adjacent shell face.

16. The non-transitory computer-readable medium of claim 13, wherein the computer-executable instructions are further configured for determining a set of parameters corresponding to the loop formed by the reference shell face and the set of consecutively adjacent shell faces, wherein the set of parameters comprises an axis of the loop, depth of the loop, and area enclosed by the loop.

17. The non-transitory computer-readable medium of claim 16, wherein determining the set of parameters corresponding to the loop formed by the reference shell face and the set of consecutively adjacent shell faces comprise:
determining the axis of the loop based on a direction of each shell edge of the reference shell edge and the set of shell edges;
calculating the depth of the loop based on a projected image length of the reference shell edge and the set of shell edges on the axis; and
calculating the area enclosed by the loop.

18. The non-transitory computer-readable medium of claim 16, wherein the through pocket validation criteria comprise:
for each shell face of the loop, determining an absence of a concave edge in a plurality of non-shell edges of the shell face within an extent of the depth;
determining an absence of an opening to access the loop in a direction other than a direction of the axis;
and
establishing the loop as a valid through pocket feature when:
the concave edge is absent in the plurality of non-shell edges, and
the opening is absent in a direction other than the direction of the axis.
